(19) United States
(12) Patent Application Publication
(10) Pub. No.: US 2003/0137815 A1
(43) Pub. Date: Jul. 24, 2003

(54) Printed wiring board and method of manufacturing the same

(75) Inventors: Shozo Ochi, Takatsuki-shi (JP); Fumio Echigo, Osaka-shi (JP); Yoji Ueda, Osaka-shi (JP); Yasushi Nakagiri, Kyotanabe-shi (JP); Takeshi Suzuki, Izumi-shi (JP)

Correspondence Address: MERCHANT & GOULD PC, P.O. BOX 2903, MINNEAPOLIS, MN, 55402-0903, US

(73) Assignee: Matsushita Electric Industrial Co., Ltd., Kadoma-shi (JP)

(21) Appl. No.: 10/340,041

(22) Filed: Jan. 9, 2003

(30) Foreign Application Priority Data
Jan. 18, 2002 (JP) 2002-009699

(51) Int. Cl. H05K 1/11; H05K 1/14

(52) U.S. Cl. 361/793

(57) ABSTRACT

An electrically insulating base material includes a core layer 102, a resin layer 101 on each surface of the core layer 102 and a conductive material 105 filled into through holes 104 formed in a thickness direction. On each surface of the electrically insulating base material, a metal foil 106 is laminated, and a laminate thus obtained is heated and pressed. A conductive filler in the conductive material 105 has a mean particle diameter equal to or larger than a thickness of the resin layer 101, and thus the conductive filler can be prevented from being diffused into the resin layer 101 in a heating and pressing process. As a result, the conductive filler can be densified, thereby allowing a printed wiring board with via hole connection having high connection reliability to be obtained.

### BACKGROUND OF THE INVENTION

1. Field of the Invention

The present invention relates to a printed wiring board on which various electronic components are mounted and a method of manufacturing the same.

2. Related Background Art

In recent years, electronic equipment has advanced in size, thickness and weight reductions as well as in performance. In such a trend, various kinds of electronic components constituting electronic equipment have become more miniaturized and thinner, and various forms of technological developments have been pursued vigorously with the purpose of enabling high-density mounting with respect to printed wiring boards on which these components are mounted.

Particularly nowadays, with the rapid development in mounting technology, it has been demanded strongly that circuit substrates with a multilayer wiring structure are made available at reduced cost, which allow bare chips of a semiconductor device such as an LSI or the like to be mounted directly and with high density on a printed wiring board, and also can be used in high-speed signal processing circuits. It is important that such a multilayer wiring circuit substrate has high electrical connection reliability between wiring patterns of a plurality of layers that are formed at a fine wiring pitch and an excellent high-frequency property. The substrate also is required to have high connection reliability with respect to semiconductor bare chips.

With the foregoing as a background, a resin multilayer wiring board in which all layers have an interstitial via hole (hereinafter, abbreviated as IVH) structure has been proposed to replace a multilayer wiring board that conventionally has been a mainstream for a wiring board realizing connection between layers by using a copper plated conductive material provided on an inner wall of each through hole (see, for example, JP 6(1994)-268345 A). In the resin multilayer wiring board, IVHs are filled with a conductive material so that connection reliability between the layers can be improved, and the IVHs can be formed directly under a land of a component or at an arbitrary position between the layers, so that a size reduction of a substrate and high-density mounting can be realized.

FIGS. 4A to 4G show a method of manufacturing a printed wiring board with an IVH structure. Initially, as shown in FIG. 4A, a releasable film 401 made of polyester or the like is laminated on each surface of a porous base material 402 formed of an aramid epoxy prepreg obtained by impregnating an aramid nonwoven fabric with a thermosetting epoxy resin.

Next, as shown in FIG. 4B, through holes 403 are formed in predetermined positions in the porous base material 402 by a laser processing method.

Then, as shown in FIG. 4C, each of the through holes 403 is filled with a conducive paste 404. This process is performed by the following method. That is, the porous base material 402 in which the through holes 403 have been formed is set on a table of a screen printing machine, and the conductive paste 404 is printed directly from above the releasable film 401. In this case, the releasable film 401 on a printed surface functions as a printing mask and also serves to prevent a surface of the porous base material 402 from being contaminated.

After that, the releasable film 401 is separated from each surface of the porous base material 402, and a metal foil 405 of copper or the like is applied on each surface of the porous base material 402.

By being heated and pressed in this state, as shown in FIG. 4D, the porous base material 402 is compressed to become thinner. In this case, the conductive paste 404 in each of the through holes 403 also is compressed. At that time, a binder component in the conductive paste 404 is pressed out, and thus binding between particles of a conductive filler and binding between the conductive filler and the metal foil 405 are strengthened, and the conductive filler in the conductive paste 404 is densified, thereby allowing an electrical connection between the metal foils 405 on both the surfaces to be obtained. After that, the thermosetting resin that is a constituent component of the porous base material 402 and the binder component of the conductive paste 404 are allowed to cure.

Then, as shown in FIG. 4E, each of the metal foils 405 is etched selectively into a predetermined pattern, and thus a dual-sided wiring board is completed.

Furthermore, as shown in FIG. 4F, porous base materials 406 in which each through hole formed in a thickness direction is filled with a conductive paste 408 by printing and metal foils 407 are laminated respectively on each side of the dual-sided wiring board. A laminate thus obtained is heated and pressed, and then the metal foil 407 on each surface is etched selectively into a predetermined pattern. Thus, a multilayer wiring board as shown in FIG. 4G is completed.

In the above-described configuration and manufacturing method, when the porous base material 402 is formed of an aramid epoxy prepreg, operation in a severe environment for electronic equipment that entails an abrupt temperature change may cause slight deterioration of a property. Thus, there has been a demand for a resin wiring board having higher reliability.

As a means for solving the above-mentioned problem, it may be considered to use a glass epoxy prepreg obtained by impregnating glass cloth with a thermosetting epoxy resin as the porous base material 402. However, with the use of the glass epoxy pregreg, since a resin layer is formed on each side of the glass cloth, the following problem has arisen. That is, when a metal foil is laminated on each side of the glass epoxy prepreg, a resin flow is caused in a heating and pressing process, so that connection reliability cannot be fulfilled.

### SUMMARY OF THE INVENTION

With the foregoing in mind, it is an object of the present invention to provide a printed wiring board that can realize highly reliable electrical connection between layers and a method of manufacturing the same.

In order to solve the afore-mentioned problem, a printed wring board according to the present invention includes an electrically insulating base material, a conductive material containing a conductive filler that is filled into through holes formed in a thickness direction of the electrically insulating base material, and a wiring layer formed into a predetermined pattern on each surface of the electrically insulating base material and connected electrically to the conductive material. The electrically insulating base material includes a core layer and a resin layer formed on each side of the core layer. The core layer includes a retaining member and a resin impregnated into the retaining member. An inorganic and/or organic filler is mixed into the resin layer. The conductive filler has a mean particle diameter equal to or larger than a thickness of the resin layer and equal to or smaller than a thickness of the electrically insulating base material.

Furthermore, a first method of manufacturing a printed wiring board according to the present invention includes the steps of: forming through holes in a thickness direction of an electrically insulating base material including a core layer formed of a prepreg obtained by impregnating a retaining member with a resin and a resin layer formed on each side of the core layer; filling the through holes with a conductive material containing a conductive filler; laminating a metal foil on each side of the electrically insulating base material; allowing the electrically insulating base material to cure, on which the metal foils have been laminated and which is compressed by heating and pressing; and forming a wiring layer by patterning the metal foils. An inorganic and/or organic filler is mixed into the resin layer. The conductive filler has a mean particle diameter equal to or larger than a thickness of the resin layer and equal to or smaller than a thickness of the electrically insulating base material.

Moreover, a second method of manufacturing a printed wiring board according to the present invention includes the steps of: forming through holes in a thickness direction of an electrically insulating base material including a core layer formed of a prepreg obtained by impregnating a retaining member with a resin and a resin layer formed on each side of the core layer; filling the through holes with a conductive material containing a conductive filler; laminating a wiring layer held by a supporting base material on each side of the electrically insulating base material; allowing the electrically insulating base material to cure, on which the wiring layers have been laminated and which is compressed by heating and pressing; and removing the supporting base material by separation. An inorganic and/or organic filler is mixed into the resin layer. The conductive filler has a mean particle diameter equal to or larger than a thickness of the resin layer and equal to or smaller than a thickness of the electrically insulating base material.

### BRIEF DESCRIPTION OF THE DRAWINGS

FIGS. 1A to 1H are cross sectional views showing process steps in order in a method of manufacturing a printed wiring board according to Embodiment 1 of the present invention.

FIGS. 2A to 2D are cross sectional views showing process steps in order in a method of manufacturing a multilayer printed wiring board according to Embodiment 2 of the present invention.

FIG. 3 is a schematic cross sectional view for explaining the behavior of a conductive filler when heated and pressed according to Embodiment 1 of the present invention.

FIGS. 4A to 4G are cross sectional views showing process steps in order in a method of manufacturing a conventional multilayer printed wiring board.

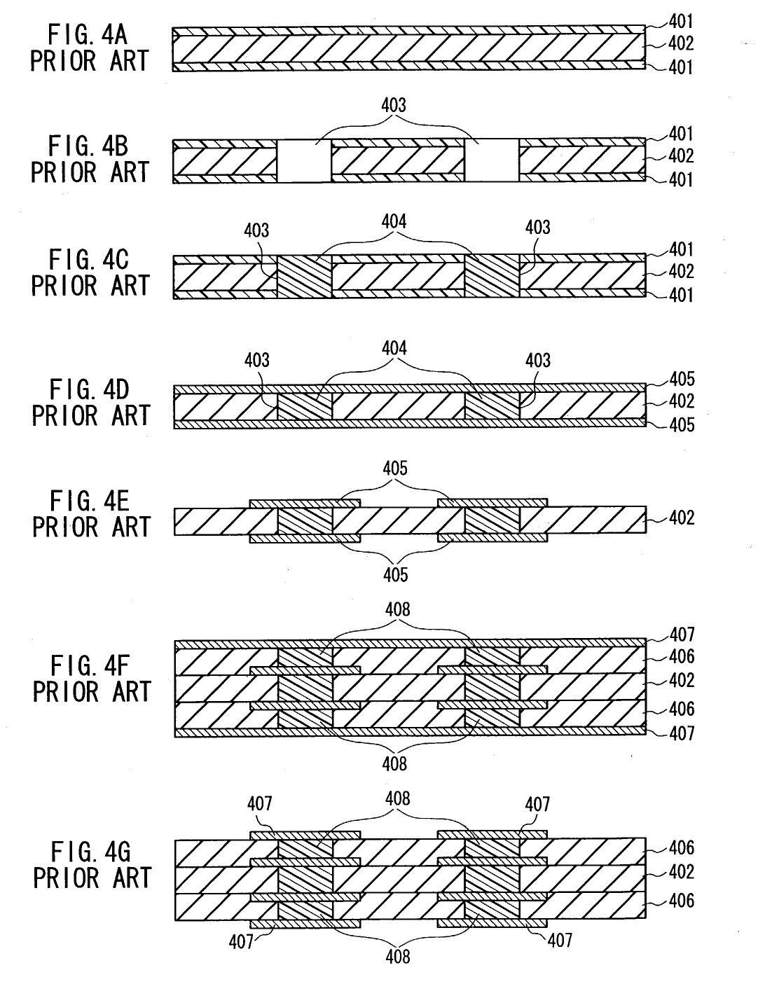

### DETAILED DESCRIPTION OF THE INVENTION

In the printed wiring board according to the present invention, the conductive filler in the conductive material has a mean particle diameter equal to or larger than the thickness of the resin layer and equal to or smaller than the thickness of the electrically insulating base material. Furthermore, the inorganic and/or organic filler is mixed into the resin layer.

Even when the resin in the resin layer melts in a heating and pressing process, since the conductive filler has a mean particle diameter equal to or larger than the thickness of the resin layer, the conductive filler can be prevented from flowing out of the through holes into the resin layers. Further, since the inorganic and/or organic filler is contained in the resin layer that is relatively thin compared with the conductive filler, the inorganic and/or organic filler functions as a shield so as to prevent the conductive filler from flowing out of the through holes into the resin layers. This synergistic effect allows the conductive filler to remain in the through holes, so that a sufficient compressive force is applied to the conductive filler. Thus, via hole connection with stable and high connection reliability can be realized.

In the present invention, the mean particle diameter of the conductive filler refers to “a median in a volume frequency distribution”.

Preferably, the conductive filler has a mean particle diameter that is not more than twice as large as the thickness of the resin layer. When the conductive filler has a particle diameter larger than that, the filling rate of the conductive filler in the conductive material is decreased, thereby decreasing a contacting area between adjacent particles of the conductive filler, so that electrical conductivity is lowered.

Furthermore, preferably, the conductive filler has a mean particle diameter of 5 to 10 μm. According to this construction, in the heating and pressing process, the conductive filler can be densified, and thus binding between the particles of the conductive filler and binding between the conductive filler and a metal foil are strengthened, thereby allowing a stable electrical connection to be obtained.

Furthermore, preferably, the inorganic and/or organic filler has a mean particle diameter of 0.5 to 3 μm. In the present invention, the mean particle diameter of the inorganic and/or organic filler refers to “a median in a volume frequency distribution”. When the inorganic and/or organic filler has a mean particle diameter larger than that, a gap between particles of the inorganic and/or organic filler in the resin layer becomes large during the heating and pressing process, thereby decreasing a filling rate of the inorganic and/or organic filler. As a result, the effect as the shield for preventing the conductive filler from flowing into the resin layers hardly can be obtained. Further, when the inorganic and/or organic filler has a mean particle diameter smaller than that, the inorganic and/or organic filler becomes likely to flow during the heating and pressing process. Also in this case, the effect as the shield of preventing the conductive filler from flowing into the resin layers hardly can be obtained. Thus, in either case, a sufficient compressive force cannot be applied to the conductive filler, thereby making it difficult to obtain stable and high connection reliability.

Furthermore, preferably, the inorganic and/or organic filler has a mean particle diameter smaller than that of the conductive filler. According to this construction in the heating and pressing process, the inorganic and/or organic filler in the resin layer is filled more densely with virtually no gaps compared to the conductive filler in the conductive material. Thus, even when the resin in the resin layer and a resin component of the conductive material flow, the conductive filler can be prevented from flowing into the resin layers by the inorganic and/or organic filler that is filled densely. As a result, a sufficient compressive force is applied to the conductive filler, thereby allowing stable and high connection reliability to be obtained.

Furthermore, preferably, the inorganic filler is formed of a powder of at least one material selected from the group consisting of SiO₂, TiO₂, Al₂O₃, MgO, SiC and AlN. According to this configuration, a mechanical strength such as a bending strength or the like further can be improved, thereby allowing a printed wiring board with excellent stiffness to be obtained.

Furthermore, preferably, the resin layer has a thickness of 3 to 20 μm. More preferably, the resin layer has a thickness of 3 to 10 μm. When using a resin layer thinner than this, the amount of the resin becomes insufficient, and thus sufficient adhesion to the metal foil hardly can be obtained. When using a resin layer thicker than this, the degree of a resin flow in the resin layer caused in the heating and pressing process is increased, and thus the conductive filler in the conductive material becomes likely to flow into the resin layer. As a result, a sufficient compressive force cannot be applied to the conductive filler, thereby making it difficult to obtain stable and high connection reliability.

Furthermore, preferably, the resin layer has a thickness larger than a mean particle diameter of the inorganic and/or organic filler. According to this configuration, adhesion between the resin in the resin layer and the metal foil can be improved. Further, in the heating and pressing process, the resin in the resin layer is allowed to flow, so that the resin layer becomes likely to be decreased in thickness. Thus, a sufficient compressive force can be applied to the conductive filler, thereby allowing stable and high connection reliability to be obtained.

Furthermore, preferably, the retaining member is formed of glass cloth. According to this configuration, when mounting electronic components or the like on a wiring pattern formed on the electrically insulating base material, a high mounting strength can be obtained.

Furthermore, preferably, each of the resin impregnated into the retaining member and the resin constituting the resin layer is a thermosetting epoxy resin. According to this configuration, adhesion between the electrically insulating base material and the metal foil and moisture resistance can be improved. Thus, the layers can be prevented from being separated during a reliability test such as a heat cycle test, a pressure cooker test or the like, thereby allowing variations in an electrical connection resistance value to be suppressed.

Furthermore, a plurality of the printed wiring boards according to the present invention may be laminated. According to this configuration, a dense wiring pattern enabling high-density mounting of microminiaturized electrical components can be formed, and a multilayer printed wiring board with excellent stiffness and hygroscopicity can be provided.

Next, in each of the first and second methods of manufacturing a printed wiring board according to the present invention, the conductive filler in the conductive material has a mean particle diameter equal to or larger than the thickness of the resin layer and equal to or smaller than the thickness of the electrically insulating base material. Further, the inorganic and/or organic filler is mixed into the resin layer.

Even when a resin in the resin layer melts during a heating and pressing process, since the conductive filler has a mean particle diameter equal to or larger than the thickness of the resin layer, the conductive filler can be prevented from flowing out of the through holes into the resin layers. Further, since the inorganic and/or organic filler is contained in the resin layer that is relatively thin compared with the conductive filler, the inorganic and/or organic filler functions as the shield so as to prevent the conductive filler from flowing out of the through holes into the resin layers. This synergistic effect allows the conductive filler to remain in the through holes, so that a sufficient compressive force is applied to the conductive filler. Thus, a printed wiring board with via hole connection having stable and high connection reliability can be provided.

In each of the above-descried methods, preferably, before forming the through holes in the electrically insulating base material, a releasable film is laminated on each surface of the electrically insulating base material, and after separating the releasable film, the metal foil (or the wiring layer) is laminated thereon. This configuration allows the releasable film to function as a printing mask. Further, a surface of the electrically insulating base material can be prevented from being contaminated, thereby allowing adhesion between the electrically insulating base material and the metal foil (or the wiring layer) to be improved.

Furthermore, preferably, the conductive material starts to cure at a temperature lower than a temperature at which the electrically insulating base material starts to cure. According to this construction, in the heating and pressing process, the conductive material starts to cure prior to the electrically insulating base material. Thus, a flow of the conductive filler in the conductive material to an exterior can be suppressed, so that the shape of each via can be retained and stable connection reliability can be obtained.

Hereinafter, the present invention will be described by way of embodiments with reference to the appended drawings. However, the present invention is not limited to the following embodiments.

### Embodiment 1

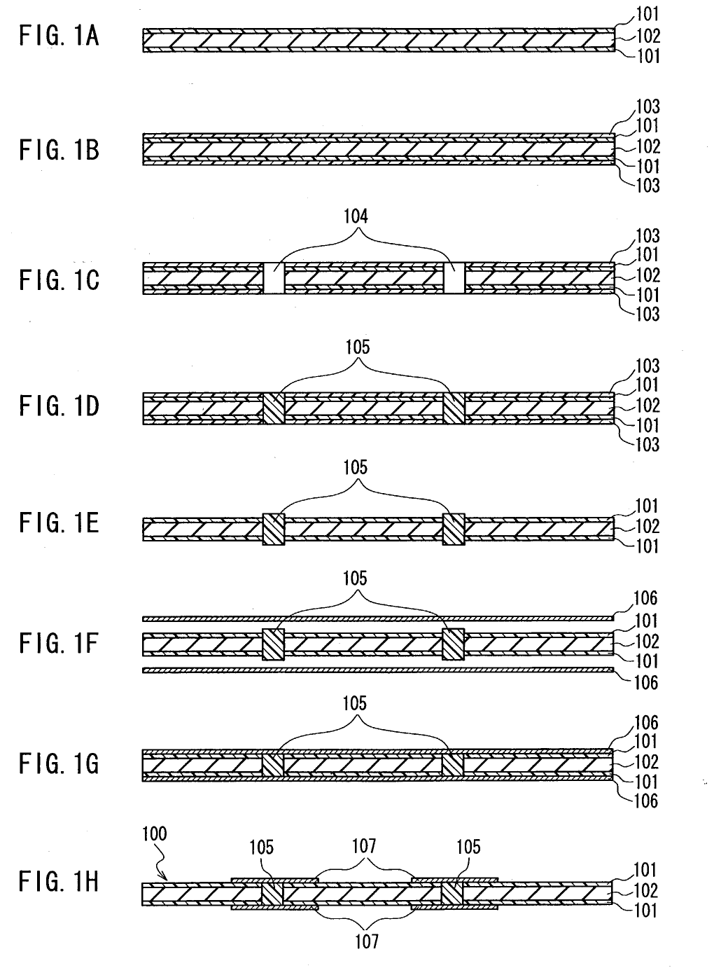

FIGS. 1A to 1F are cross sectional views showing process steps in a method of manufacturing a dual-sided wiring board according to Embodiment 1 of the present invention.

Initially, as shown in FIG. 1A, a prepreg having a total thickness of 114 μm was prepared. The prepreg included a core layer 102 obtained by impregnating a 100 μm thick retaining member formed of glass cloth with a thermoplastic epoxy resin into which SiC particles having a mean particle diameter of 2 μm were mixed, and a 7 μm thick resin layer 101 formed on each side of the core layer 102. The resin layer 101 was made of the same type of thermosetting epoxy resin as that impregnated into the core layer 102, into which SiC particles having a mean particle diameter of 2 μm were mixed.

It also is possible to use an electrically insulating base material in which a glass nonwoven fabric is used in place of the glass cloth, and a resin layer is formed on each surface of the glass nonwoven fabric.

Furthermore, the material of the particles is not limited to SiC and may be one material or a mixture of two or more materials selected from the group consisting of inorganic fillers of SiO₂, TiO₂, Al₂O₃, MgO and AlN and organic fillers of benzoguanamine, polyamide, polyimide, a melamine resin, an epoxy resin and the like. A mixture of inorganic and organic fillers also may be used.

Next, as shown in FIG. 1B, a releasable film 103 made of polyester was laminated on each surface of the prepreg. Lamination was performed at a temperature of about 120° C. Thus, the resin layer 101 on each surface of the prepreg melted slightly, thereby allowing the releasable film 103 to be laminated. As the releasable film, a 19 μm thick film of polyethylene terephthalate (PET) was used. The releasable film 103 can be made of polyester or a resin other than PET.

Next, as shown in FIG. 1C, through holes 104 were formed in predetermined positions in the prepreg by a laser processing method. Each of the through holes 104 formed by a laser processor had a diameter of about 200 μm When the through holes 104 are formed by the laser processing method, formation of through holes having a fine diameter according to a finer wiring pattern can be performed easily at high speed.

Next, as shown in FIG. 1D, a conductive paste 105 was filled into the through holes 104. This process was performed by the following method. That is, the conductive paste 105 was printed directly from above the releasable film 103 by using a screen printing machine. In this case, a resin component (binder component) in the conductive paste 105 in each of the through holes 104 was vacuum-drawn from a side opposite a printed surface through a porous sheet of, for example, Japanese paper, so that a ratio of the conductive filler was increased, thereby allowing the conductive filler to be filled more densely.

The conductive filler can be formed of a metallic filler in common use. For example, particles of at least one material selected from the group consisting of copper, gold, platinum, silver, palladium, nickel, tin, lead and an alloy of some of these materials can be used.

Furthermore, the resin component of the conductive paste may be formed of, for example, a glycidyl ether-type epoxy resin such as a bisphenol F-type epoxy resin, a bisphenol A-type epoxy resin or a bisphenol AD-type epoxy resin, a cycloaliphatic epoxy resin, a glycidylamine-type epoxy resin, and a glycidyl ester-type epoxy resin.

When filling the conductive paste 105 by a printing method, the releasable film 103 functions as a printing mask and also serves to prevent a surface of the prepreg from being contaminated.

The conductive filler in the conductive paste 105 had a mean particle diameter of 10 μm. This diameter is larger than a thickness of the resin layer 101 and a particle diameter of particles contained in the resin layer 101.

Next, as shown in FIG. 1E, the releasable film 103 was separated from each surface of the prepreg. Then, as shown in FIG. 1F, a metal foil 106 of copper or the like was laminated on each surface of the prepreg, and a laminate thus obtained was heated and pressed by a vacuum press.

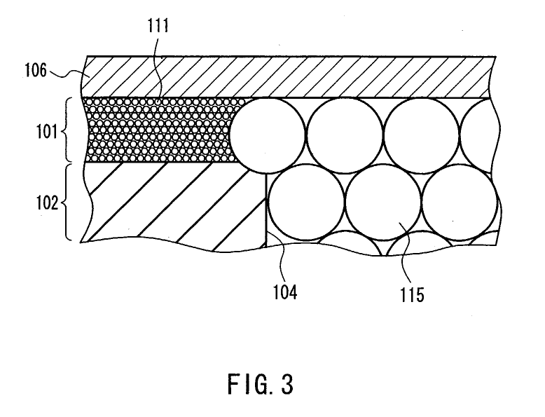

FIG. 3 is a cross sectional view of the laminate immediately after being heated and pressed. In the figure, reference numerals 111 and 115 denote particles mixed into the resin layer 101 and a conductive filler constituting the conductive paste filled into the through holes 104, respectively. In practice, the particles 111 also are mixed into the core layer 102, which is not shown in the figure. As shown in FIG. 3, since the conductive filler 115 has a mean particle diameter larger than the thickness of the resin layer 101, even when a resin in the resin layer 101 and the resin component in the conductive paste melt and flow during a heating and pressing process, the conductive filler 115 can be prevented from flowing out of the through holes 104 provided in the core layer 102 into the resin layer 101. Further, the resin in the resin layer 101 flows into the core layer 102, and thus a filling rate of the particles 111 in the resin layer 101 is increased. The particles 111 that are filled densely prevent the conductive filler 115 from flowing into the resin layer 101 (an effect of the particles as “a shield”). This synergistic effect allows the conductive filler 115 to remain in the through holes 104, so that a sufficient compressive force is applied to the conductive filler 115. Thus, via hole connection with stable and high connection reliability can be realized.

By continuing the heating and pressing process in this state, as shown in FIG. 1G, the prepreg was compressed to be thinner. In this case, the conductive paste 105 in the through holes 104 also was compressed. At that time, the resin component in the conductive paste 105 was pressed out, and thus binding between the particles of the conductive filler 115 and binding between the conductive filler 115 and the metal foil 106 were strengthened, and the conductive filler 115 in the conductive paste 105 was densified. After that, the thermosetting resin in each of the resin layer 101 and the core layer 102 that is a constituent component of the prepreg and the resin component in the conductive paste 105 were allowed to cure.

Finally, as shown in FIG. 1H, each of the metal foils 106 was etched selectively into a predetermined pattern, and thus a wiring layer 107 was formed on each side of the prepreg. In this manner, a dual-sided wiring board 100 was completed in which the wiring layers 107 on both sides were connected electrically to each other by the conductive paste 105.

The printed wiring board 100 according to this embodiment has an improved mounting strength of electronic components and excellent connection reliability and hygroscopicity.

### Embodiment 2

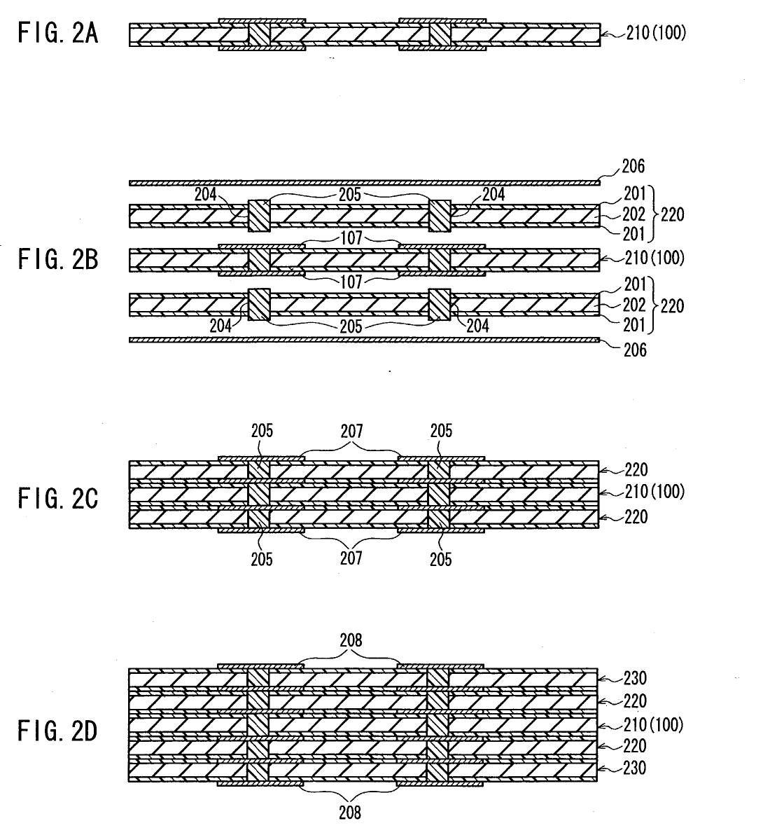

FIGS. 2A to 2D are cross sectional views showing process steps in a method of manufacturing a dual-sided wiring board according to Embodiment 2 of the present invention.

Initially, as shown in FIG. 2A, a core substrate 210 manufactured in the same manner as in the case of the dual-sided wiring board 100 of Embodiment 1 shown in FIG. 1H was prepared.

Next, as shown in FIG. 2B, an electrically insulating base material 220 having the same configuration as that in Embodiment 1 shown in FIG. 1E was laminated on each side of the core substrate 210. Then, on each side of a laminate thus obtained, a metal foil 206 was laminated, and a laminate thus obtained was heated and pressed by a vacuum heat press.

As shown in FIG. 2C, by this heating and pressing process, each of the electrically insulating base materials 220 was compressed to become thinner, and wiring layers 107 of the core substrate 210 were embedded respectively in the electrically insulating base materials 220. In this case, a conductive paste 205 in the electrically insulating base materials 220 was compressed, and thus a binder component in the conductive paste 205 was pressed out. As a result, binding between particles of a conductive filler and binding between the conductive filler and the metal foil 206 (and the wiring layer 107) were strengthened, and the conductive filler in the conductive paste 205 was densified. As in Embodiment 1, the conductive filler has a mean particle diameter larger than a thickness of a resin layer 201 of the electrically insulating base material 220. Thus, even when a resin in the resin layer 201 and a resin component in the conductive paste 205 melt and flow, the conductive filler can be prevented from flowing out of through holes 204 provided in each core layer 202 of the electrically insulating base materials 220 to an exterior. After that, a thermosetting resin in each of the resin layer 201 and the core layer 202 of the electrically insulating base material 220 and the resin component in the conductive paste 205 were allowed to cure.

Furthermore, as shown in FIG. 2C, each of the metal foils 206 was etched selectively into a predetermined pattern, and thus wiring layers 207 were formed. In this manner, a four-layer wiring board in which the wiring layers 107 and the wiring layers 207 were connected electrically by the conductive paste 205 was completed.

Finally, as shown in FIG. 2D, an electrically insulating base material 230 having the same configuration as that in Embodiment 1 shown in FIG. 1E was laminated on each side of the above-described four-layer wiring board. Then, on each side of a laminate thus obtained, a metal foil was laminated. After following the same processes as those shown in FIGS. 2B and 2C, a six-layer wiring board in which the wiring layers 207 and wiring layers 208 on each side were connected electrically was completed.

The six-layer wiring board according to this embodiment is a multilayer printed wiring board that allows a dense wiring pattern enabling high-density mounting of microminiaturized electric components to be formed and has excellent stiffness and hygroscopicity.

In Embodiment 2, the dual-sided wiring board 100 manufactured in Embodiment 1 was used as the core substrate 210. However, the present invention is not limited thereto and can provide the same effect when using a commonly used dual-sided or multilayer board.

Embodiments 1 and 2 were directed to an example in which the core layer included a base material formed of glass cloth. However, the present invention is not limited thereto and can provide the same effect when using a base material of, for example, aromatic polyamide, a glass nonwoven fabric, an aramid fabric, an aramid nonwoven fabric or the like.

Furthermore, in each of Embodiments 1 and 2, the resin layer was made of a thermosetting epoxy resin. However, the present invention is not limited thereto and can provide the same effect when using, for example, a phenol resin, a naphthalene resin, a urea resin, an amino resin, an alkyd resin, a silicon resin, a furan resin, an unsaturated polyester resin, a polyurethane resin or the like.

Furthermore, in each of Embodiments 1 and 2, the wiring layer on the printed wiring board was formed by etching the metal foil after being laminated on the surface of the electrically insulating base material. However, the present invention is not limited thereto. For example, the wiring layer can be formed by transferring a wiring layer obtained by etching a metal foil laminated on a supporting base material onto an electrically insulating base material. That is, in FIG. 1F (or FIG. 2B), in place of the metal foil 106 (or the metal foil 206), a wiring layer formed beforehand on a supporting base material by patterning is laminated together with the supporting base material. After a heating and pressing process, the supporting base material is separated to be removed, and thus the wiring layer can be transferred onto a side of the electrically insulating base material. In this case, the wiring layer that has been transferred is embedded in the resin layer on a side onto which the wiring layer is to be transferred as in the case of the wiring layer 107 described with regard to Embodiment 2. In this manner, the same effect as that provided by Embodiments 1 and 2 also can be obtained.

The invention may be embodied in other forms without departing from the spirit or essential characteristics thereof The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A printed wiring board, comprising:
an electrically insulating base material;
a conductive material containing a conductive filler that is filled into through holes formed in a thickness direction of the electrically insulating base material; and
a wiring layer formed into a predetermined pattern on each surface of the electrically insulating base material and connected electrically to the conductive material,
wherein the electrically insulating base material comprises a core layer and a resin layer formed on each side of the core layer,
the core layer comprises a retaining member and a resin impregnated into the retaining member,
an inorganic and/or organic filler is mixed into the resin layer, and
the conductive filler has a mean particle diameter equal to or larger than a thickness of the resin layer and equal to or smaller than a thickness of the electrically insulating base material.

2. The printed wiring board according to claim 1, wherein the conductive filler has a mean particle diameter that is not more than twice as large as the thickness of the resin layer.

3. The printed wiring board according to claim 1, wherein the conductive filler has a mean particle diameter of 5 to 10 μm.

4. The printed wiring board according to claim 1, wherein the inorganic and/or organic filler has a mean particle diameter of 0.5 to 3 μm.

5. The printed wiring board according to claim 1, wherein the inorganic and/or organic filler has a mean particle diameter smaller than that of the conductive filler.

6. The printed wiring board according to claim 1, wherein the inorganic filler is formed of a powder of at least one material selected from the group consisting of SiO₂, TiO₂, Al₂O₃, MgO, SiC and AlN.

7. The printed wiring board according to claim 1, wherein the resin layer has a thickness of 3 to 20 μm.

8. The printed wiring board according to claim 1, wherein the resin layer has a thickness larger than a mean particle diameter of the inorganic and/or organic filler.

9. The printed wiring board according to claim 1, wherein the retaining member is formed of glass cloth.

10. The printed wiring board according to claim 1, wherein each of the resin impregnated into the retaining member and a resin constituting the resin layer is a thermosetting epoxy resin.

11. A printed wiring board product comprising a laminate of a plurality of printed wiring boards as claimed in claim 1.

12. A method of manufacturing a printed wiring board, comprising the steps of:
forming through holes in a thickness direction of an electrically insulating base material comprising a core layer formed of a prepreg obtained by impregnating a retaining member with a resin and a resin layer formed on each side of the core layer;
filling the through holes with a conductive material containing a conductive filler;
laminating a metal foil on each side of the electrically insulating base material;
allowing the electrically insulating base material to cure, on which the metal foils have been laminated and which is compressed by heating and pressing; and
forming a wiring layer by patterning the metal foils,
wherein an inorganic and/or organic filler is mixed into the resin layer, and
the conductive filler has a mean particle diameter equal to or larger than a thickness of the resin layer and equal to or smaller than a thickness of the electrically insulating base material.

13. A method of manufacturing a printed wiring board, comprising the steps of:
forming through holes in a thickness direction of an electrically insulating base material comprising a core layer formed of a prepreg obtained by impregnating a retaining member with a resin and a resin layer formed on each side of the core layer;
filing the through holes with a conductive material containing a conductive filler;
laminating a wiring layer held by a supporting base material on each side of the electrically insulating base material;
allowing the electrically insulating base material to cure, on which the wiring layers have been laminated and which is compressed by heating and pressing; and
removing the supporting base material,
wherein an inorganic and/or organic filler is mixed into the resin layer, and
the conductive filler has a mean particle diameter equal to or larger than a thickness of the resin layer and equal to or smaller than a thickness of the electrically insulating base material.

14. The method according to claim 12,
wherein before forming the through holes in the electrically insulating base material, a releasable film is laminated on each surface of the electrically insulating base material, and
after separating the releasable film, the metal foil is laminated thereon.

15. The method according to claim 13,
wherein before forming the through holes in the electrically insulating base material, a releasable film is laminated on each surface of the electrically insulating base material, and
after separating the releasable film, the wiring layer is laminated thereon.

16. The method according to claim 12 or 13, wherein the conductive material starts to cure at a temperature lower than a temperature at which the electrically insulating base material starts to cure.
